(19) United States
(12) Patent Application Publication
(10) Pub. No.: US 2021/0214840 A1
(43) Pub. Date: Jul. 15, 2021

(54) VAPOR DEPOSITION STRUCTURE, VAPOR DEPOSITION DEVICE, VAPOR DEPOSITION SYSTEM, AND METHOD OF USING VAPOR DEPOSITION STRUCTURE

(71) Applicants: BOE Technology Group Co., Ltd., Beijing (CN); Chengdu BOE Optoelectronics Technology Co., Ltd., Chengdu, Sichuan (CN)

(72) Inventors: Yong Rao, Beijing (CN); Youliang Li, Beijing (CN); Jinbiao Liu, Beijing (CN); Rui Tan, Beijing (CN); Xiaofei Yue, Beijing (CN); Nan Luo, Beijing (CN); Bin Hu, Beijing (CN); Xiuchao Yi, Beijing (CN); Meng Shen, Beijing (CN); Xinxing Jia, Beijing (CN); Peng Xiao, Beijing (CN); Jing Li, Beijing (CN); Yajie Jin, Beijing (CN)

(21) Appl. No.: 16/959,196

(22) PCT Filed: Jan. 8, 2020
(86) PCT No.: PCT/CN2020/071013

§ 371 Date: Jun. 30, 2020

(30) Foreign Application Priority Data
Jan. 24, 2019 (CN) 201910069733.3

(51) Int. Cl. C23C 14/24; C23C 16/455; C23C 16/458

(52) U.S. Cl. CPC C23C 14/243; C23C 16/4582; C23C 16/45563

(57) ABSTRACT

A vapor deposition structure includes: a vapor deposition crucible, a nozzle and a floating plate. The vapor deposition crucible is configured to receive a vapor deposition source material, and the vapor deposition source material transitions from a liquid state to a gaseous state after being heated. The nozzle is disposed at an outlet of the vapor deposition crucible. The nozzle is configured to spray the vapor deposition source material in the gaseous state onto a surface of a substrate under vapor deposition. The floating plate is configured to float on a surface of the vapor deposition source material in the liquid state. The floating plate is provided with a plurality of hollowed-out structures. The plurality of hollowed-out structures are configured to allow the vapor deposition source material in the gaseous state to pass through.

The present disclosure claims priority to Chinese Patent Application No. 201910069733.3, filed on Jan. 24, 2019 and entitled “VAPOR DEPOSITION STRUCTURE, VAPOR DEPOSITION DEVICE, VAPOR DEPOSITION SYSTEM, AND METHOD OF USING VAPOR DEPOSITION STRUCTURE”, the entire contents of which are incorporated herein by reference.

### TECHNICAL FIELD

The present discourse relates to the field of display technologies, and more particularly to a vapor deposition structure, a vapor deposition device, a vapor deposition system, and a method of using a vapor deposition structure.

### BACKGROUND

In the preparation process of an organic light-emitting diode (OLED) display panel, a vapor deposition method is often adopted to prepare a film.

In the related art, the vapor deposition method mainly forms a film on a substrate under vapor deposition by spraying a vapor deposition source material onto the substrate under vapor deposition by using a vapor deposition structure. The vapor deposition structure generally includes a vapor deposition crucible and a nozzle at an outlet of the vapor deposition crucible. The implementation process of the vapor deposition method is: placing a solid or liquid vapor deposition source material in a vapor deposition crucible, heating the vapor deposition source material by means of resistance heating or the like, such that the vapor deposition source material becomes gaseous after being heated, controlling the vapor deposition crucible to move from one end to the other end of the substrate under vapor deposition, and in the process of movement, controlling the nozzle to spray the vapor deposition source material in a gaseous state to the surface of the substrate under vapor deposition, such that the vapor deposition source material is deposited on the surface of the substrate under vapor deposition.

### SUMMARY

The present disclosure provides a vapor deposition structure, a vapor deposition device, a vapor deposition system, and a method of using a vapor deposition structure. The technical solutions are as follows.

In one aspect, a vapor deposition structure is provided. The vapor deposition structure includes a vapor deposition crucible, a nozzle and a floating plate, wherein
the vapor deposition crucible is configured to receive a vapor deposition source material, and the vapor deposition source material transitions from a liquid state to a gaseous state after being heated;
the nozzle is disposed at an outlet of the vapor deposition crucible, and the nozzle is configured to spray the vapor deposition source material in the gaseous state onto a surface of a substrate under vapor deposition; and
the floating plate is configured to float on a surface of the vapor deposition source material in the liquid state, and the floating plate is provided with a plurality of hollowed-out structures, the plurality of hollowed-out structures being configured to allow the vapor deposition source material in the gaseous state to pass through.

Optionally, the floating plate is a hollow plate-like structure.

Optionally, the floating plate includes a plurality of connecting cylinders, and a back plate and a cover plate oppositely disposed, the back plate being provided with a plurality of first through holes, and the cover plate being provided with a plurality of second through holes corresponding to the plurality of first through holes; wherein
one connecting cylinder is hermetically connected to the back plate at one first through hole, and hermetically connected to the cover plate at one second through hole corresponding to the one first through hole to obtain one hollowed-out structure; and
the back plate is hermetically connected to the cover plate at a position on an edge of the back plate where the first through hole is not provided and at a position on an edge of the cover plate where the second through hole is not provided to obtain a hermetical cavity.

Optionally, the back plate and the cover plate are both curved plate-like structures;

Optionally, one of the back plate and the cover plate is a curved plate-like structure, and the other is a flat plate-like structure;

Optionally, the back plate and the cover plate are both flat plate-shaped structures.

The floating plate further includes a connecting plate, and the back plate is hermetically connected to the cover plate by the connecting plate at the position on the edge of the back plate where the first through hole is not provided and at the position on the edge of the cover plate where the second through hole is not provided.

Optionally, the floating plate is a solid plate-like structure.

A density of the floating plate is less than a density of the vapor deposition source material in the liquid state.

Optionally, a material of the floating plate is a thermally conductive material.

Optionally, a surface of the floating plate that is in contact with the vapor deposition source material is provided with a layer of thermally conductive material.

Optionally, the plurality of hollow structures are evenly distributed on the surface of the floating plate.

Optionally, the floating plate is provided with a plurality of regions, and the hollow structures in different regions have different distribution densities.

Optionally, the floating plate is provided with a plurality of regions, and the hollow structures in different regions have different opening sizes.

Optionally, a distribution density of the plurality of hollow structures increases as the distance between the hollow structure and the edge of the floating plate increases.

Optionally, an opening size of the plurality of hollow structures increases as the distance between the hollow structure and the edge of the floating plate increases.

Optionally, the vapor deposition structure further includes a connecting plate, the floating plate is a hollow plate-like structure, the material of the floating plate is a thermally conductive material, and the floating plate includes a plurality of connecting cylinders and a back plate and a cover plate oppositely disposed, the back plate being provided with a plurality of first through holes, and the cover plate being provided with a plurality of second through holes corresponding to the plurality of first through holes; wherein
one connecting cylinder is hermetically connected to the back plate at one first through hole, and hermetically connected to the cover plate at one second through hole corresponding to the one first through hole to obtain one hollowed-out structure;
the back plate is hermetically connected to the cover plate at the position on the edge of the back plate where the first through hole is not provided and at the position on the edge of the cover plate where the second through hole is not provided to obtain a hermetical cavity; and
the floating plate is provided with a plurality of regions, the hollowed-out structures in different regions have different distribution densities, and the hollowed-out structures in different regions have different opening sizes.

Further, a vapor deposition device is provided. The device includes a carrying tank and at least one vapor deposition structure, the vapor deposition structure including a vapor deposition crucible, a nozzle and a floating plate, wherein
the vapor deposition crucible is configured to receive a vapor deposition source material, and the vapor deposition source material transitions from a liquid state to a gaseous state after being heated;
the nozzle is disposed at an outlet of the vapor deposition crucible, and the nozzle is configured to spray the vapor deposition source material in the gaseous state onto a surface of a substrate under vapor deposition; and
the floating plate is configured to float on a surface of the vapor deposition source material in the liquid state, and the floating plate is provided with a plurality of hollowed-out structures, the plurality of hollowed-out structures being configured to allow the vapor deposition source material in the gaseous state to pass through.

In another aspect, a vapor deposition system is provided. The system includes a vapor deposition chamber and a vapor deposition device inside the vapor deposition chamber, the vapor deposition device being any of the above vapor deposition devices.

In another aspect, a method of using a vapor deposition structure is provided. The vapor deposition structure includes a vapor deposition crucible, a nozzle, and a floating plate. The method includes:
placing a vapor deposition source material and the floating plate into the vapor deposition crucible in sequence;
installing the nozzle at an outlet of the vapor deposition crucible; and
heating the vapor deposition source material such that the vapor deposition source material transitions from a liquid state to a gaseous state after being heated, and spraying the vapor deposition source material in the gaseous state from the nozzle to a surface of a substrate under vapor deposition;
wherein the floating plate is configured to float on a surface of the vapor deposition source material in the liquid state, and the floating plate is provided with a plurality of hollowed-out structures, the plurality of hollowed-out structures being configured to allow the vapor deposition source material in the gaseous state to pass through.

### BRIEF DESCRIPTION OF THE DRAWINGS

In order to explain the technical solutions in the embodiments of the present disclosure more clearly, the drawings required for the description of the embodiments may be briefly introduced below. Obviously, the drawings in the following description are only some embodiments of the present disclosure. For those of ordinary skill in the art, without paying any creative labor, other drawings may be obtained based on these drawings.

FIG. 1 is a schematic structural diagram of a vapor deposition structure in a related art;

FIG. 2 is a schematic structural diagram of a vapor deposition structure according to an embodiment of the present disclosure;

FIG. 3 is a schematic structural diagram of another vapor deposition structure according to an embodiment of the present disclosure;

FIG. 4 is a schematic structural diagram of a vapor deposition structure in another related art;

FIG. 5 is a top view of a floating plate according to an embodiment of the present disclosure;

FIG. 6 is a schematic structural diagram of yet another vapor deposition structure according to an embodiment of the present disclosure;

FIG. 7 is a top view of another floating plate according to an embodiment of the present disclosure;

FIG. 8 is a top view of yet another floating plate according to an embodiment of the present disclosure;

FIG. 9 is a schematic cross-sectional view of a floating plate according to an embodiment of the present disclosure;

FIG. 10 is a schematic cross-sectional view of another floating plate according to an embodiment of the present disclosure;

FIG. 11 is a schematic cross-sectional view of still another floating plate according to an embodiment of the present disclosure;

FIG. 12 is a schematic cross-sectional view of yet another floating plate according to an embodiment of the present disclosure;

FIG. 13 is a schematic cross-sectional view of still another floating plate according to an embodiment of the present disclosure;

FIG. 14 is a flowchart of a method of using a vapor deposition structure according to an embodiment of the present disclosure;

FIG. 15 is a schematic structural diagram of a vapor deposition device according to an embodiment of the present disclosure;

FIG. 16 is a schematic structural diagram of a vapor deposition system according to an embodiment of the present disclosure.

### DETAILED DESCRIPTION

To make the principles and advantages of the present disclosure clearer, the embodiments of the present disclosure may be described in further detail below with reference to the accompanying drawings.

Generally, when a vapor deposition structure is not moved, the liquid levels of a vapor deposition source material in the vapor deposition crucible at different positions are the same; and when the vapor deposition structure moves, under the action of inertia, the vapor deposition source material in the liquid state may shake in the vapor deposition crucible, resulting in that the liquid levels of the vapor deposition source material are different at different positions in the vapor deposition crucible. For example, referring to FIG. 1, when the moving direction X of the vapor deposition structure is horizontal right, under the action of inertia, the liquid level h1 of the vapor deposition source material L in the liquid state proximal to the left inner wall of the vapor deposition crucible 01 is greater than the liquid level height h2 of the vapor deposition source material L in the liquid state proximal to the right inner wall of the vapor deposition crucible 01.

When the vapor deposition source material in the liquid state has different liquid levels at different positions in the vapor deposition crucible, the pressure distribution of the vapor deposition source material in the gaseous state in the vapor deposition crucible may be caused to be uneven, which causes the pressure of the vapor deposition source material in the gaseous state at the inlets of different nozzle 02 to be different.

The great the pressure of the vapor deposition source material in the gaseous state at the inlet of the nozzle 02, the more the vapor deposition source material sprayed by the nozzle 02 onto the surface of a substrate under vapor deposition (not shown in FIG. 1) per unit time, and accordingly, the thicker the vapor deposition source material deposited on the substrate under vapor deposition. Therefore, when the pressure of the vapor deposition source material in the gaseous state at the inlets of different nozzle 02 is different, it is easy for the vapor deposition source materials formed on the substrate under vapor deposition to have different thicknesses, resulting in poor uniformity of the film formed on the substrate under vapor deposition.

An embodiment of the present disclosure provides a vapor deposition structure, which can reduce the shaking amplitude of a vapor deposition source material in a liquid state in a vapor deposition crucible when the vapor deposition structure moves, and can effectively improve the uniformity of a film formed on a substrate under vapor deposition.

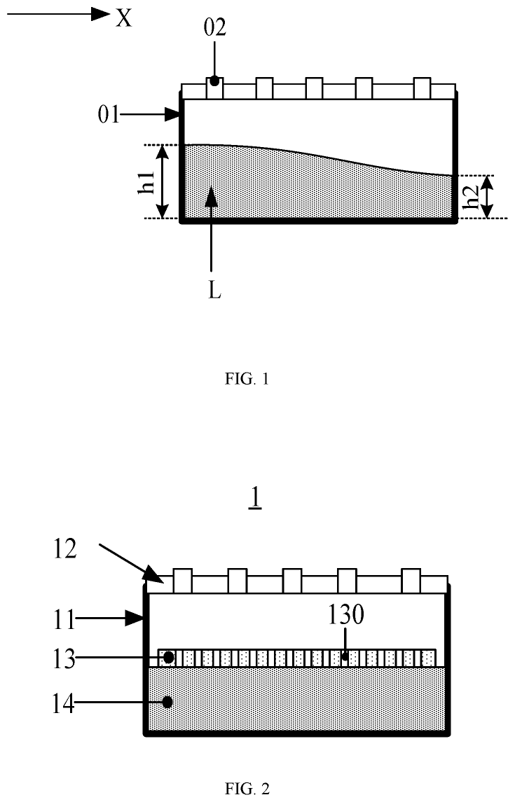

FIG. 2 is a schematic structural diagram of a vapor deposition structure according to an embodiment of the present disclosure. As shown in FIG. 2, the vapor deposition structure 1 may include a vapor deposition crucible 11, a nozzle 12 and a floating plate 13.

The vapor deposition crucible 11 is configured to receive a vapor deposition source material. The vapor deposition source material transitions from a liquid state to a gaseous state after being heated. The vapor deposition source material may be in the liquid state when it is not heated (that is, at a normal temperature), and may be in the gaseous state after being heated. Alternatively, the vapor deposition source material may be in the solid state when it is not heated, and when heated, the material transitions from a solid state to the liquid state, and then from the liquid state to the gaseous state. In this case, the vapor deposition source material may be called a molten vapor deposition source material.

The nozzle 12 is disposed at an outlet of the vapor deposition crucible 11. The nozzle 12 is configured to spray the vapor deposition source material in the gaseous state onto a surface of a substrate under vapor deposition.

The floating plate 13 is configured to float on a surface of the vapor deposition source material 14 in the liquid state. In this case, a gap is defined between the floating plate 13 and an inner wall of the vapor deposition crucible 11. The floating plate 13 is provided with a plurality of hollowed-out structures 130. The plurality of hollowed-out structures 130 are configured to allow the vapor deposition source material in the gaseous state to pass through. The vapor deposition source material in the gaseous state can reach the nozzle 12 after passing through the plurality of hollowed-out structures, such that the nozzle 12 can spray the vapor deposition source material in the gaseous state onto the surface of the substrate under vapor deposition to form a film on the substrate under vapor deposition.

In summary, by means of the vapor deposition structure according to an embodiment of the present disclosure, the power required for shaking the vapor deposition source material in the liquid state in the vapor deposition crucible is increased and the shaking amplitude of the vapor deposition source material in the liquid state in the vapor deposition crucible under the same magnitude of power is reduced by enabling the floating plate to float on the surface of the vapor deposition source material in the liquid state; and because of the gap between the floating plate and the inner wall of the vapor deposition crucible, the floating plate can collide with the inner wall of the vapor deposition crucible and generate a force opposite to the shaking direction of the vapor deposition source material in the liquid state, which force can weaken the shaking amplitude of the vapor deposition source material in the liquid state in the vapor deposition crucible. Compared with the related art, the level difference at different positions in the vapor deposition crucible is reduced, the pressure difference at the inlets of different nozzle is reduced, the uniformity of the amount of the vapor deposition source material sprayed from different nozzles to the surface of the substrate under vapor deposition is improved, and the uniformity of the film formed on the substrate under vapor deposition is further improved.

Since the floating plate 13 floats on the surface of the vapor deposition source material 14 in the liquid state, it can be determined that a gap is defined between the floating plate 13 and the inner wall of the vapor deposition crucible 11. Referring to FIG. 2, assuming that the vapor deposition structure 1 moves in the horizontal right direction, the shaking force of the vapor deposition source material 14 in the liquid state is horizontal left, and under the action of the horizontal left force, the floating plate 13 floating on the surface of the vapor deposition source material 14 in the liquid state also moves to the left, and the floating plate 13 hits the left inner wall of the vapor deposition crucible 11. When the floating plate 13 hits the left inner wall of the vapor deposition crucible 11, the floating plate 13 may receive a horizontal right force and move horizontally to the right under the action of the horizontal right force. When the floating plate 13 moves horizontally to the right, since the floating plate 13 is in contact with the surface of the vapor deposition source material 14 in the liquid state, the floating plate 13 exerts a horizontal right frictional force on the vapor deposition source material 14 in the liquid state. In addition, since a part of the vapor deposition source material 14 in the liquid state may be immersed in the gap surrounded by the hollowed-out structure 130 of the floating plate 13, the floating plate 13 may apply a horizontal right reaction force to the part of the vapor deposition source material 14 in the liquid state. Since the direction of the frictional force and the direction of the reaction force are opposite to the direction of the force that causes the vapor deposition source material 14 in the liquid state to shake, the frictional force and the reaction force can partially cancel the force that causes the vapor deposition source material 14 in the liquid state to shake, such that the shaking amplitude of the vapor deposition source material 14 in a liquid state can be reduced.

Optionally, the width of the gap between the floating plate 13 and the inner wall of the vapor deposition crucible 11 is set according to application requirements. For example, the width of the gap between the floating plate 13 and the inner wall of the vapor deposition crucible 11 may be smaller than a reference width, such that when the vapor deposition source material 14 in the liquid state shakes within the vapor deposition crucible 11 to a small extent, the floating plate 13 can collide with the inner wall of the vapor deposition crucible 11 and the sensitivity of the floating plate 13 to generate a reaction force according to the vapor deposition source material 14 is improved.

During the operation of the vapor deposition structure, since the pressure of the vapor deposition source material in the gaseous state in the vapor deposition crucible is higher than that of the vapor deposition source material outside the vapor deposition crucible, the vapor deposition source material in the gaseous state can be spontaneously sprayed from the nozzle to the surface of the substrate under vapor deposition under the effect of the pressure difference. Alternatively, the nozzle may be provided with a pressurization component. In this case, the pressurization component may pressurize the vapor deposition source material in the gaseous state at the nozzle to spray the vapor deposition source material in the gaseous state to the surface of the substrate under vapor deposition.

Optionally, there may be a plurality of implementations to heat the vapor deposition source material. In one implementation, the vapor deposition crucible can have a heating function. In this case, the vapor deposition crucible can directly heat the vapor deposition source material, such that the vapor deposition source material becomes gaseous after being heated. In another implementation, a heating device may be adopted to heat the vapor deposition source material. For example, the heating device may heat the vapor deposition crucible, and the vapor deposition crucible transfers the received heat to the vapor deposition source material, such that the vapor deposition source material transitions to a gaseous state after being heated.

Alternatively, the material of the floating plate may be a thermally conductive material having thermal conductivity. For example, the material of the floating plate may be metal or a composite thermally conductive material with thermal conductivity (such as graphene or thermal grease). When the material of the floating plate 13 is a material having thermal conductivity, the vapor deposition source material proximal to the inner wall of the vapor deposition crucible 11 can transfer a part of heat to the floating plate 13. The heat transferred to the floating plate 13 can be transferred to the vapor deposition source material at a position more distal from the inner wall of the vapor deposition crucible by the floating plate 13. When the thermal conductivity of the material of the floating plate 13 is higher than the thermal conductivity of the vapor deposition source material, more heat can be transferred to the vapor deposition source material at a position more distal from the inner wall of the vapor deposition crucible. Therefore, the vapor deposition source material at a position more distal from the inner wall of the vapor deposition crucible can have a relatively high temperature, the temperature difference between the vapor deposition source material at a position farther away from the inner wall of the vapor deposition crucible and the vapor deposition source material proximal to the inner wall of the vapor deposition crucible can be reduced, and the heating uniformity of the vapor deposition source material in the vapor deposition crucible is improved, such that the rates of the vapor deposition source material at different positions of the vapor deposition crucible transitioning from a liquid state to a gaseous state are relatively close, which further reduces the pressure difference between the vapor deposition source materials in the gaseous states at the inlets of different nozzle.

Alternatively, the surface of the floating plate 13 that is in contact with the vapor deposition source material 14 may be provided with a layer of thermally conductive material. The layer of thermally conductive material can transfer heat between the vapor deposition source materials at different positions, and can further reduce the pressure difference between the vapor deposition source materials at the inlets of different nozzle. The layer of thermally conductive material may be a film made of a thermally conductive material. Alternatively, the layer of thermally conductive material may be a thermally conductive silicon tape or a thermally conductive tape. Moreover, when a layer of thermally conductive material is provided on the floating plate 13, the material of the floating plate 13 may be a thermally conductive material, or may be a non-thermally conductive material, which is not specifically limited in the embodiments of the present disclosure.

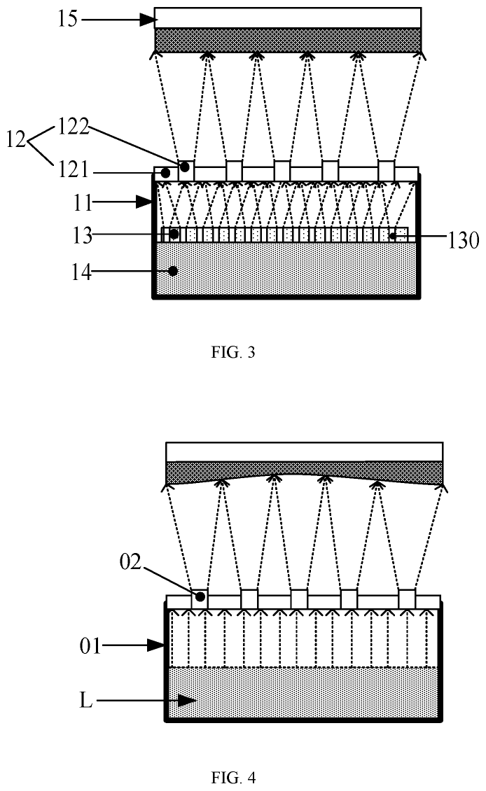

Optionally, with continued reference to FIG. 3, the nozzle 12 may include a nozzle holder 121 and a nozzle head 122. The nozzle holder 121 is disposed at the outlet of the vapor deposition crucible. The nozzle head 122 is provided on the nozzle holder 121. The nozzle head 122 is configured to spray the vapor deposition source material in the gaseous state onto a surface of a substrate 15 under vapor deposition. The nozzle holder 121 is detachably connected to the vapor deposition crucible. Exemplarily, the connection between the nozzle holder 121 and the vapor deposition crucible may be a snap connection.

In the embodiments of the present disclosure, since the floating plate is provided with a plurality of hollowed-out structures 130, when the vapor deposition source material in the gaseous state flows out from an end of the hollowed-out structure 130 proximal to the nozzle, the flow trajectory of the vapor deposition source material in the gaseous state is no longer a flow in the vertical direction in the related art (as shown in FIG. 4), but a divergent flow at an outlet of the hollowed-out structure 130 (as shown in FIG. 3). That is, its flow trajectory can meet Knud Mori distribution. In this case, vapor deposition source materials in the gaseous state flowing out from different hollowed-out structures 130 can be mixed with each other, and heat exchange can be realized between the mixed vapor deposition source materials, which further improves the temperature uniformity in the vapor deposition crucible and reduces the pressure difference at different nozzle inlets.

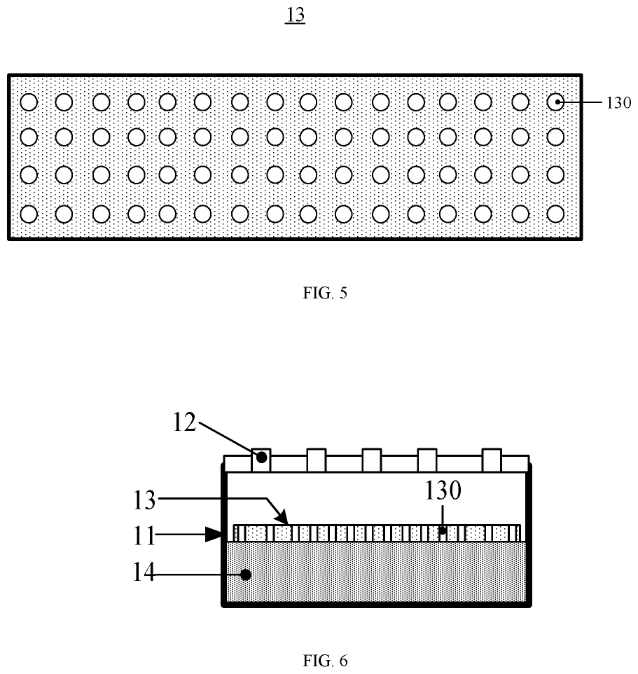

In one implementation, the plurality of hollowed-out structures can be evenly distributed on the surface of the floating plate. For example, as shown in FIG. 5, the plurality of hollowed-out structures 130 are evenly distributed on the surface of the floating plate. In this case, the amount of the vapor deposition source material in the gaseous state passing through each hollowed-out structure 130 is substantially the same.

In another implementation, the plurality of hollowed-out structures may be unevenly distributed on the surface of the floating plate. For example, the floating plate may have a plurality of regions. The distribution densities of the hollowed-out structures 130 in different regions are different, and/or the opening sizes of the hollowed-out structures 130 in different regions are different.

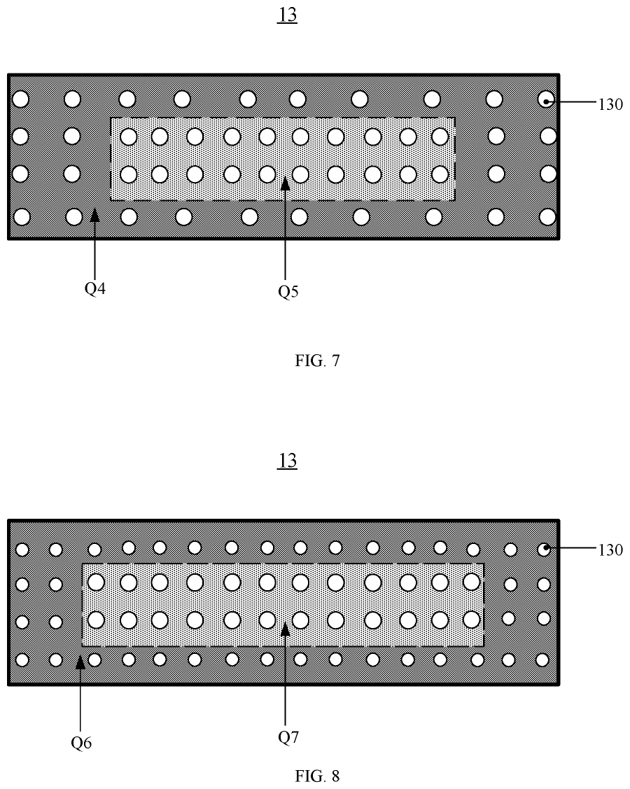

Optionally, when the distribution densities of the hollowed-out structures 130 in different regions are different (as shown in FIGS. 6 and 7), the hollowed-out structures 130 in the same region may also be evenly or unevenly distributed in this region. When the opening sizes of the hollowed-out structures 130 in different regions are different, the opening sizes of the hollowed-out structures in the same region may also be the same or different, which is not limited in the embodiments of the present disclosure. For example, FIG. 7 is a schematic top view of the floating plate in FIG. 6. As shown in FIG. 7, the distribution density of the hollowed-out structures 130 in a region Q4 proximal to the inner wall of the vapor deposition crucible (not shown) is less than that of the hollowed-out structures 130 in a region Q5 more distal from the inner wall of the vapor deposition crucible.

As one implementation, when the floating plate is provided with a plurality of regions and the opening sizes of the hollowed-out structures 130 in different regions are different, the opening sizes of the hollowed-out structures 130 in a region of the floating plate 13 proximal to the inner wall of the vapor deposition crucible may be smaller than the opening sizes of the hollowed-out structures 130 in a region more distal from the inner wall of the vapor deposition crucible. For example, as shown in FIG. 8, the opening sizes of the hollowed-out structures 130 in a region Q6 proximal to the inner wall of the vapor deposition crucible (not shown) is smaller than the opening sizes of the hollowed-out structures 130 in a region Q7 more distal from the inner wall of the vapor deposition crucible. That is, the opening ratio of the region Q6 proximal to the inner wall of the vapor deposition crucible is smaller than the opening ratio of the region Q7 more distal from the inner wall of the vapor deposition crucible.

In another case of uneven distribution, the distribution density and/or opening size of the hollowed-out structure may increase as the distance between the hollowed-out structure and the edge of the floating plate increases.

When the plurality of hollowed-out structures are unevenly distributed on the surface of the floating plate, the distribution density and/or opening size of the hollowed-out structures can balance the non-uniformity of the amount of the vapor deposition source material in a gaseous sate arriving at different positions caused by uneven heating of the vapor deposition source material, in order to make the amount of the vapor deposition source material in the gaseous state flowing out of the hollowed-out structures 130 at different positions and reaching the inlet of the nozzle (not shown) as equal as possible, and the amount of the vapor deposition source material sprayed by different nozzles to the surface of the substrate under vapor deposition within unit time also as equal as possible, thereby improving the uniformity of the thickness of the film formed on the substrate under vapor deposition.

In addition, in a region where a hollowed-out structure 130 with a small opening is located, the vapor deposition source material in the gaseous state between the floating plate and the surface of the vapor deposition source material in the liquid state can be recycled to a hollowed-out structure 130 with a large opening, and reach the nozzle by the hollowed-out structure 130 with a large opening, which increases the amount of the vapor deposition source material in the gaseous state flowing out of the hollowed-out structure 130 with a large opening and reaching the inlet of the nozzle, and further reduces the pressure difference of the vapor deposition source material in the gaseous state at the inlets of different nozzle.

Optionally, the circumscribed graphics of the cross-sections of the plurality of hollowed-out structures on the floating plate in the extending direction of the floating plate may be circular, rectangular, or triangular, etc., which is not limited in the embodiments of the present disclosure. FIG. 5, FIG. 7 and FIG. 8 are schematic diagrams showing that the circumscribed graphics of a plurality of hollowed-out structures in the extending direction of the floating plate are circular.

Furthermore, the floating plate 13 may be a solid plate-like structure or a hollow plate-like structure.

When the floating plate 13 is a solid plate-like structure, the density of the floating plate 13 is less than the density of the vapor deposition source material 14 in the liquid state to ensure that the floating plate 13 can float on the surface of the vapor deposition source material 14 in the liquid state. Exemplarily, the floating plate may be made of a material capable of enabling the floating plate to float on the surface of the vapor deposition source material in the liquid state, such as resin or titanium alloy. In this case, the manufacturing process of the floating plate 13 is relatively simple. Exemplarily, when manufacturing the floating plate, a hole punching tool may be directly adopted to punch holes in a pre-formed plate-like structure to form a plurality of hollowed-out structures 130 on the floating plate 13.

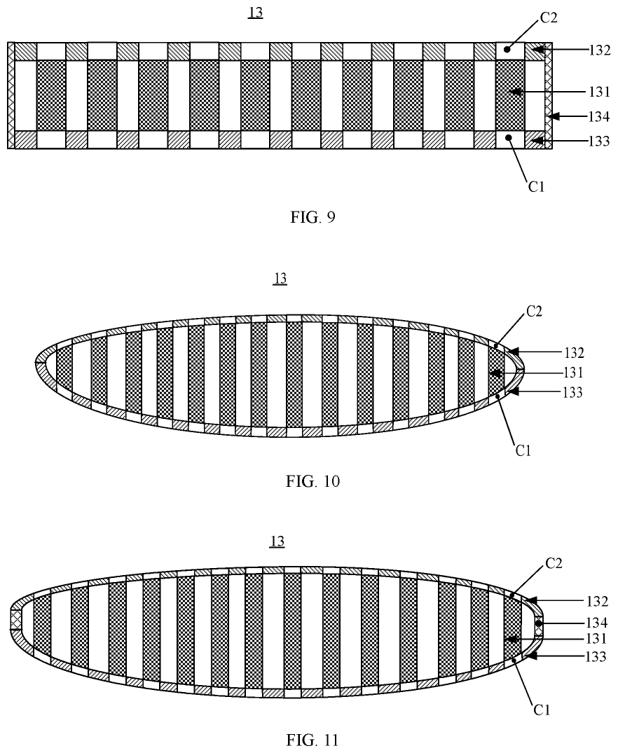

When the floating plate 13 is a hollow plate-like structure, as shown in FIG. 9, the floating plate 13 may include a plurality of connecting cylinders 131 and a back plate 133 and a cover plate 132 oppositely disposed. The back plate 133 is provided with a plurality of first through holes C1. The cover plate 132 is provided with a plurality of second through holes C2 corresponding to the plurality of first through holes C1 respectively. One of the back plate 133 and the cover plate 132 is in contact with the surface of the vapor deposition source material in the liquid state. The embodiment of the present disclosure takes the back plate 133 being in contact with the surface of the vapor deposition source material in the liquid state as an example for description.

For each connecting cylinder 131, any one of the connecting cylinders 131 may be hermetically connected to the back plate 133 at one first through hole C1, and hermetically connected to the cover plate 132 at one second through hole C2 corresponding to the one first through hole C1 to obtain a hollowed-out structure (not shown). After the plurality of connecting cylinders 131 are hermetically connected to the back plate 133 and the cover plate 132 respectively in the above manner, a plurality of hollowed-out structures can be obtained.

Further, the back plate 133 may be hermetically connected to the cover plate 132 at a position on an edge of the back plate 133 where the first through hole C1 is not provided and at a position on an edge of the cover plate 132 where the second through hole C2 is not provided to obtain a hermetical cavity surrounded by the back plate 133, the cover plate 132, and the plurality of connecting cylinders 131. Exemplarily, the position on the edge of the back plate 133 where the first through hole C1 is not provided may be any position in the edge area of the back plate 133, and the position on the edge of the cover plate 132 where the second through hole C2 is not provided may be any position in the edge area of the cover plate 132.

The hermetical connection between the connecting cylinder 131 and the back plate 133 and the hermetical connection between the connecting cylinder 131 and the cover plate 132 may be detachable connections or non-detachable connections. Exemplarily, the detachable connection may be a snap connection or an adhesive connection. The non-detachable connection may be welding or the like.

Optionally, the connection between the back plate 133 and the cover plate 132 may be realized in a plurality of manners. The following may be used as an example to describe the embodiments of the present disclosure.

In a first implementation, the back plate 133 and the cover plate 132 may be both flat plate-shaped structures. In this case, the floating plate 13 may further include a connecting plate 134. The back plate 133 and the cover plate 132 may also be connected by this connecting plate 134.

As shown in FIG. 9, when the back plate 133 and the cover plate 132 are both flat plate-like structures, the position on the edge of the back plate 133 where the first through hole C1 is not provided is hermetically connected to the position on the edge of the cover plate 132 where the second through hole C2 is not provided by the connecting plate 134.

Optionally, the hermetical connection between the connecting plate 134 and the back plate 133 and the hermetical connection between the connecting plate 134 and the cover plate 132 may be detachable connections or non-detachable connections. When the connection between the connecting plate 134 and the back plate 133 and the connection between the connecting plate 134 and the cover plate 132 are detachable connections, the detachable connection may be a snap connection or an adhesive connection. When the connection between the connecting plate 134 and the back plate 133 and the connection between the connecting plate 134 and the cover plate 132 are non-detachable connections, the non-detachable connection may be welding or the like.

In a second implementation, the back plate 133 and the cover plate 132 may both be curved plate-like structures. In this case, the back plate 133 and the cover plate 132 may be directly connected or connected by the connecting plate 134.

As shown in FIG. 10, the side of the back plate 133 facing the connecting cylinder may be concave, and the side of the cover plate 132 facing the connecting cylinder may be convex. In this case, the position on the edge of the back plate 133 where the first through hole C1 is not provided is directly hermetically connected to the position on the edge of the cover plate 132 where the second through hole C2 to form a floating plate.

The connection between the back plate 133 and the cover plate 132 may be a snap connection or an adhesive connection. Optionally, when the materials of the back plate 133 and the cover plate 132 are both metals, the connection between the back plate 133 and the cover plate 132 may also be welding.

As shown in FIG. 11, the side of the back plate 133 facing the connecting cylinder may be concave, and the side of the cover plate 132 facing the connecting cylinder may be convex. The position on the edge of the back plate 133 where the first through hole C1 is not provided is hermetically connected to the position on the edge of the cover plate 132 where the second through hole C2 is not provided by the connecting plate 134. The position on the edge of the back plate 133 where the first through hole C1 is not provided is hermetically connected to one end of the connecting plate 134, and the other end of the connecting plate 134 is hermetically connected to the position on the edge of the cover plate 132 where the second through hole C2 is not provided.

In a third implementation, one of the back plate 133 and the cover plate 132 is a curved plate-like structure, and the other is a flat plate-like structure. In this case, the back plate 133 and the cover plate 132 may be directly connected or connected by the connecting plate 134.

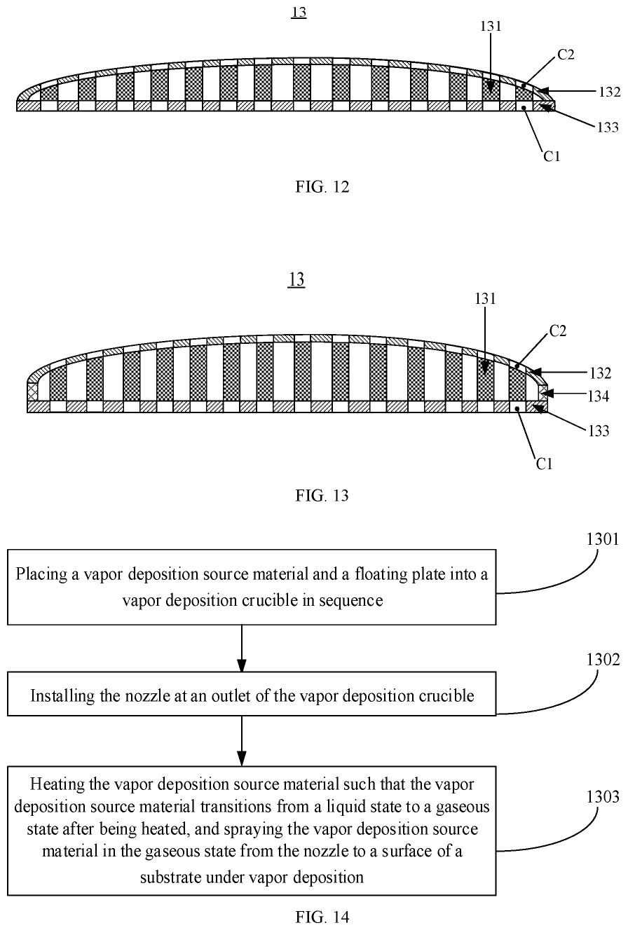

As shown in FIG. 12, the back plate 133 is a flat plate-like structure, the cover plate 132 is a curved plate-like structure, and the side of the cover plate 132 facing the connecting cylinder may be convex. The position on the edge of the back plate 133 where the first through hole C1 is not provided is directly hermetically connected to the position on the edge of the cover plate 132 where the second through hole C2 is not provided

The connection between the back plate 133 and the cover plate 132 may be a snap connection or an adhesive connection. Optionally, when the materials of the back plate 133 and the cover plate 132 are both metals, the connection between the back plate 133 and the cover plate 132 may also be welding.

As shown in FIG. 13, the back plate 133 is a flat plate-like structure, the cover plate 132 is a curved plate-like structure, and the side of the cover plate 132 facing the connecting cylinder may be convex. The position on the edge of the back plate 133 where the first through hole C1 is not provided is hermetically connected to the position on the edge of the cover plate 132 where the second through hole C2 is not provided by the connecting plate 134. The position on the edge of the back plate 133 where the first through hole C1 is not provided is hermetically connected to one end of the connecting plate 134, and the other end of the connecting plate 134 is hermetically connected to the position on the edge of the cover plate 132 where the second through hole C2 is not provided.

In summary, by means of the vapor deposition structure according to an embodiment of the present disclosure, the power required for shaking the vapor deposition source material in the liquid state in the vapor deposition crucible is increased and the shaking amplitude of the vapor deposition source material in the liquid state in the vapor deposition crucible under the same magnitude of power is reduced by enabling the floating plate to float on the surface of the vapor deposition source material in the liquid state; and because of the gap between the floating plate and the inner wall of the vapor deposition crucible, the floating plate can collide with the inner wall of the vapor deposition crucible and generate a force opposite to the shaking direction of the vapor deposition source material in the liquid state, which force can weaken the shaking amplitude of the vapor deposition source material in the liquid state in the vapor deposition crucible. Compared with the related art, the level difference at different positions in the vapor deposition crucible is reduced, the pressure difference at the inlets of different nozzle is reduced, the uniformity of the amount of the vapor deposition source material sprayed from different nozzles to the surface of the substrate under vapor deposition is improved, and the uniformity of the film formed on the substrate under vapor deposition is further improved.

FIG. 14 is a flowchart of a method of using a vapor deposition structure according to an embodiment of the present disclosure. The vapor deposition structure may be any vapor deposition structure in the foregoing embodiments. The method of using a vapor deposition structure may include the following steps.

In step 1301, a vapor deposition source material and a floating plate are placed in order in a vapor deposition crucible.

In step 1302, a nozzle is installed at an outlet of the vapor deposition crucible.

In step 1303, the vapor deposition source material is heated such that the vapor deposition source material transitions from a liquid state to a gaseous state after being heated, and the vapor deposition source material in the gaseous state is sprayed from the nozzle to a surface of a substrate under vapor deposition.

The floating plate is configured to float on a surface of the vapor deposition source material in the liquid state. There is a gap between the floating plate and an inner wall of the vapor deposition crucible. The floating plate is provided with a plurality of hollowed-out structures. The plurality of hollowed-out structures are configured to allow the vapor deposition source material in the gaseous state to pass through.

Moreover, when the vapor deposition structure includes a plurality of vapor deposition crucibles, different vapor deposition materials may be held in different vapor deposition crucibles to form different films on the vapor deposition substrate. In this case, the vapor deposition crucible can be controlled to move from one end to the other end of the substrate under vapor deposition to control the nozzles on different vapor deposition crucibles to spray the vapor deposition source material in the gaseous state onto the surface of the substrate under vapor deposition, thereby forming different films on the surface of the substrate under vapor deposition.

In summary, by means of the method of using a vapor deposition structure according to an embodiment of the present disclosure, the power required for shaking the vapor deposition source material in the liquid state in the vapor deposition crucible is increased and the shaking amplitude of the vapor deposition source material in the liquid state in the vapor deposition crucible under the same magnitude of power is reduced by placing the vapor deposition source material and the floating plate in order in the vapor deposition crucible and enabling the floating plate to float on the surface of the vapor deposition source material in the liquid state; and because of the gap between the floating plate and the inner wall of the vapor deposition crucible, the floating plate can collide with the inner wall of the vapor deposition crucible and generate a force opposite to the shaking direction of the vapor deposition source material in the liquid state, which force can weaken the shaking amplitude of the vapor deposition source material in the liquid state in the vapor deposition crucible. Compared with the related art, the level difference at different positions in the vapor deposition crucible is reduced, the pressure difference at the inlets of different nozzle is reduced, the uniformity of the amount of the vapor deposition source material sprayed from different nozzles to the surface of the substrate under vapor deposition is improved, and the uniformity of the film formed on the substrate under vapor deposition is further improved.

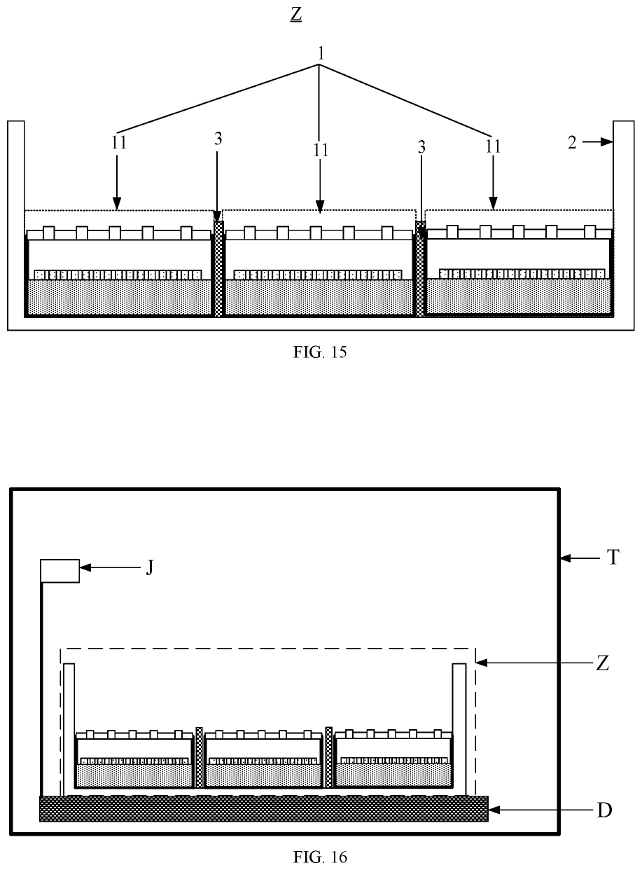

FIG. 15 is a schematic structural diagram of a vapor deposition device according to an embodiment of the present disclosure. As shown in FIG. 15, the vapor deposition device Z may include a carrying tank 2 and at least one vapor deposition structure 1. When the vapor deposition device Z includes a plurality of vapor deposition structures 1, the vapor deposition device Z further includes at least one separator 3 disposed between every two vapor deposition crucibles 11. FIG. 15 is a schematic view of a vapor deposition device including one vapor deposition structure 1 and two separators 3, and a vapor deposition structure 1 including three vapor deposition crucibles 11.

An inner wall of the carrying tank 2 is provided with a groove in which a heating device (not shown) for heating the vapor deposition structure 1 and the at least one separator 3 is embedded. Exemplarily, the heating device may be a resistance wire. In this case, an electric current may be supplied to the heating device, such that the heating device heats the vapor deposition structure 1 and the at least one separator 3.

When the vapor deposition device Z includes a plurality of vapor deposition structures 1, the plurality of vapor deposition structures 1 are sequentially arranged in the carrying tank 2 along the extending direction of the carrying tank 2, and the plurality of vapor deposition structures 1 may be any vapor deposition structure 1 according to an embodiment of the present disclosure. The at least one separator 3 is fixedly connected to the inner wall of the carrying tank and is in contact with an outer wall of the vapor deposition crucible 11 in the vapor deposition structure 1. The at least one separator 3 is configured to separate two adjacent vapor deposition crucibles 11, and heat the vapor deposition crucible 11 in contact with the at least one separator 3.

An embodiment of the present disclosure also provides a vapor deposition system. As shown in FIG. 16, the vapor deposition system may include a vapor deposition chamber T, and a vapor deposition device Z, a power device D, and a detection device J inside the vapor deposition chamber T.

The power device is fixedly connected to the carrying tank in the vapor deposition device. The power device is configured to drive the vapor deposition device to move in the vapor deposition chamber to vapor deposit the substrate under vapor deposition.

The detection device is fixedly connected to the power device. The detection device is configured to detect the flow rate of the vapor deposition source material in the gaseous state in the vapor deposition chamber, and feedback the information of the flow rate to the power device, such that the power device can adjust the moving speed of the power device according to the flow rate. The detection device may be a quartz crystal microbalance (QCM). When the nozzle sprays the vapor deposition source material in the gaseous state into the vapor deposition chamber, the vapor deposition source material in the gaseous state may fall on the surface of the quartz crystal microbalance, which can detect the mass of the vapor deposition source material in the gaseous state falling on its surface, and according to the detected mass, output an electrical signal with a certain frequency by a quartz crystal oscillation circuit, such that other auxiliary equipment such as a computer can obtain the detected mass according to the electrical signal, and determine the flow rate of the vapor deposition source material in the gaseous state in the vapor deposition chamber according to the mass.

In summary, the vapor deposition system according to an embodiment of the present disclosure includes a vapor deposition structure and the vapor deposition structure includes a floating plate. The power required for shaking the vapor deposition source material in the liquid state in the vapor deposition crucible is increased and the shaking amplitude of the vapor deposition source material in the liquid state in the vapor deposition crucible under the same magnitude of power is reduced by enabling the floating plate to float on the surface of the vapor deposition source material in the liquid state; and because of the gap between the floating plate and the inner wall of the vapor deposition crucible, the floating plate can collide with the inner wall of the vapor deposition crucible and generate a force opposite to the shaking direction of the vapor deposition source material in the liquid state, which force can weaken the shaking amplitude of the vapor deposition source material the a liquid state in the vapor deposition crucible. Compared with the related art, the level difference at different positions in the vapor deposition crucible is reduced, the pressure difference at the inlets of different nozzle is reduced, the uniformity of the amount of the vapor deposition source material sprayed from different nozzles to the surface of the substrate under vapor deposition is improved, and the uniformity of the film formed on the substrate under vapor deposition is further improved.

Described above are merely optional embodiments of the present disclosure and not intended to limit the present disclosure. Any modifications, equivalent replacements, improvements, or the like made within the spirit and principles of the present disclosure shall be included in the scope of protection of the present disclosure.

What is claimed is:

1. A vapor deposition structure, comprising: a vapor deposition crucible, a nozzle, and a floating plate; wherein the vapor deposition crucible is configured to receive a vapor deposition source material, the vapor deposition source material transitions from a liquid state to a gaseous state after being heated;
the nozzle is disposed at an outlet of the vapor deposition crucible, and the nozzle is configured to spray the vapor deposition source material in the gaseous state onto a surface of a substrate under vapor deposition; and
the floating plate is configured to float on a surface of the vapor deposition source material in the liquid state, and the floating plate is provided with a plurality of hollowed-out structures, the plurality of hollowed-out structures being configured to allow the vapor deposition source material in the gaseous state to pass through.

2. The vapor deposition structure according to claim 1, wherein the floating plate is a hollow plate-like structure.

3. The vapor deposition structure according to claim 2, wherein the floating plate comprises a plurality of connecting cylinders, and a back plate and a cover plate oppositely disposed, the back plat is provided with a plurality of first through holes, and the cover plate is provided with a plurality of second through holes corresponding to the plurality of first through holes respectively; wherein
one connecting cylinder is hermetically connected to the back plate at one first through hole, and hermetically connected to the cover plate at one second through hole corresponding to the one first through hole to obtain one hollowed-out structure; and
the back plate is hermetically connected to the cover plate at a position on an edge of the back plate where the first through hole is not provided and at a position on an edge of the cover plate where the second through hole is not provided to obtain a hermetical cavity.

4. The vapor deposition structure according to claim 3, wherein the back plate and the cover plate are both curved plate-like structures.

5. The vapor deposition structure according to claim 3, wherein one of the back plate and the cover plate is a curved plate-like structure, and the other is a flat plate-like structure.

6. The vapor deposition structure according to claim 3, wherein the back plate and the cover plate are both flat plate-like structures.

7. The vapor deposition structure according to claim 6, wherein the floating plate further comprises a connecting plate, and the back plate is hermetically connected to the cover plate by the connecting plate at the position on the edge of the back plate where the first through hole is not provided and at the position on the edge of the cover plate where the second through hole is not provided.

8. The vapor deposition structure according to claim 1, wherein the floating plate is a solid plate-like structure.

9. The vapor deposition structure according claim 1, wherein a density of the floating plate is less than a density of the vapor deposition source material in the liquid state.

10. The vapor deposition structure according to claim 1, wherein a material of the floating plate is a thermally conductive material.

11. The vapor deposition structure according to claim 1, wherein a surface of the floating plate that is in contact with the vapor deposition source material is provided with a layer of thermally conductive material.

12. The vapor deposition structure according to claim 1, wherein the plurality of hollowed-out structures are evenly distributed on the surface of the floating plate.

13. The vapor deposition structure according to claim 1, wherein the floating plate is provided with a plurality of regions, and the hollowed-out structures in different regions have different distribution densities.

14. The vapor deposition structure according to claim 1, wherein the floating plate is provided with a plurality of regions, and the hollowed-out structures in different regions have different opening sizes.

15. The vapor deposition structure according to claim 1, wherein the distribution density of the plurality of hollowed-out structures increases as the distance between the hollowed-out structure and the edge of the floating plate increases.

16. The vapor deposition structure according to claim 1, wherein an opening size of the plurality of hollowed-out structures increases as the distance between the hollowed-out structure and the edge of the floating plate increases.

17. The vapor deposition structure according to claim 1, further comprising a connecting plate, wherein
the floating plate is a hollow plate-shaped structure, the material of the floating plate is a thermally conductive material, and the floating plate comprises a plurality of connecting cylinders and a back plate and a cover plate oppositely disposed, the back plate being provided with a plurality of first through hole, and the cover plate being provided with a plurality of second through holes corresponding to the plurality of first through holes respectively; wherein
one connecting cylinder is hermetically connected to the back plate at one first through hole, and hermetically connected to the cover plate at one second through hole corresponding to the one first through hole to obtain one hollowed-out structure;
the back plate is hermetically connected to the cover plate at the position on the edge of the back plate where the first through hole is not provided and at the position on the edge of the cover plate where the second through hole is not provided to obtain a hermetical cavity; and
the floating plate is provided with a plurality of regions, the hollowed-out structures in different regions have different distribution densities, and the hollowed-out structures in different regions have different opening sizes.

18. A vapor deposition device, comprising: a carrying tank and at least one vapor deposition structure, the vapor deposition structure comprising: a vapor deposition crucible, a nozzle and a floating plate, wherein
the vapor deposition crucible is configured to receive a vapor deposition source material, and the vapor deposition source material transitions from a liquid state to a gaseous state after being heated;
the nozzle is disposed at an outlet of the vapor deposition crucible, and the nozzle is configured to spray the vapor deposition source material in the gaseous state onto a surface of a substrate under vapor deposition; and
the floating plate is configured to float on a surface of the vapor deposition source material in the liquid state, and the floating plate is provided with a plurality of hollowed-out structures, the plurality of hollowed-out structures being configured to allow the vapor deposition source material in the gaseous state to pass through.

19. A vapor deposition system, comprising: a vapor deposition chamber, and a vapor deposition device inside the vapor deposition chamber, the vapor deposition device being a vapor deposition device according to claim 18.

20. A method of using a vapor deposition structure, the vapor deposition structure comprising: a vapor deposition crucible, a nozzle and a floating plate, the method comprising:
placing a vapor deposition source material and the floating plate into the vapor deposition crucible in sequence;
installing the nozzle at an outlet of the vapor deposition crucible; and
heating the vapor deposition source material such that the vapor deposition source material transitions from a liquid state to a gaseous state after being heated, and spraying the vapor deposition source material in the gaseous state from the nozzle to a surface of a substrate under vapor deposition;
wherein the floating plate is configured to float on a surface of the vapor deposition source material in the liquid state, and the floating plate is provided with a plurality of hollowed-out structures, the plurality of hollowed-out structures being configured to allow the vapor deposition source material in the gaseous state to pass through.
